(19) United States
(12) Patent Application Publication
(10) Pub. No.: US 2025/0079240 A1
(43) Pub. Date: Mar. 6, 2025

(54) SEMICONDUCTOR DEVICE AND MANUFACTURING METHOD THEREOF

(71) Applicants: Kabushiki Kaisha Toshiba, Tokyo (JP); Toshiba Electronic Devices & Storage Corporation, Tokyo (JP)

(72) Inventor: Masaaki OGAWA, Hakusan Ishikawa (JP)

(21) Appl. No.: 18/435,865

(22) Filed: Feb. 7, 2024

(30) Foreign Application Priority Data
Sep. 6, 2023 (JP) 2023-144353

(51) Int. Cl. H01L 21/78; H01L 29/06

(52) U.S. Cl. CPC H01L 21/78; H10D 62/117

(57) ABSTRACT

A semiconductor device according to the present embodiment includes a semiconductor element having a first face, a second face located on an opposite side to the first face, and a side face located between the first face and the second face. A first electrode layer is provided on the first face of the semiconductor element. A second electrode layer is provided on the second face of the semiconductor element. An outer edge portion on the second face is more rounded compared to an outer edge portion on the first face. A thickness of the second electrode layer gradually decreases as the second electrode layer extends closer to the side face.

### CROSS REFERENCE TO RELATED APPLICATIONS

This application is based upon and claims the benefit of priority from the prior Japanese Patent Application No. 2023-144353, filed on Sep. 6, 2023, the entire contents of which are incorporated herein by reference.

### FIELD

The embodiments of the present invention relate to a semiconductor device and a manufacturing method thereof.

### BACKGROUND

A semiconductor-chip dicing process is performed by forming a backside electrode on a semiconductor wafer after grinding the semiconductor wafer into a thin film, and cutting the backside electrode using a blade. However, when the backside electrode is cut using the blade, burrs are formed thereon. The burrs may cut deep into a dicing sheet. In this case, it is difficult to pick up the semiconductor chips from the dicing sheet. The burrs formed on the backside electrode may cause a short circuit failure between terminals, or may cause cracks on the end face of the semiconductor chips.

Laser dicing reduces or prevents formation of burrs on the backside electrode. However, there is still a concern about possible damage to the semiconductor chips due to using a laser. The grooving width of the laser extends about twice the width of a dicing line. Accordingly, in an assembly process, resin enters a portion of the backside chip end from which metal has been removed. This raises a concern that the resin may affect the properties of semiconductor devices.

### BRIEF DESCRIPTION OF THE DRAWINGS

FIG. 1 is a partial cross-sectional view illustrating a configuration example of a semiconductor device according to an embodiment;

FIG. 2 is a cross-sectional view illustrating an example of a manufacturing method of the semiconductor device according to the embodiment;

FIG. 3 is a cross-sectional view illustrating an example of the manufacturing method of the semiconductor device in continuation from FIG. 2;

FIG. 4 is a cross-sectional view illustrating an example of the manufacturing method of the semiconductor device in continuation from FIG. 3;

FIG. 5A is a cross-sectional view illustrating an example of the manufacturing method of the semiconductor device in continuation from FIG. 4;

FIG. 5B is a cross-sectional view illustrating an example of the manufacturing method of the semiconductor device in continuation from FIG. 4;

FIG. 6A is a cross-sectional view illustrating an example of the manufacturing method of the semiconductor device in continuation from FIG. 5A;

FIG. 6B is a cross-sectional view illustrating an example of the manufacturing method of the semiconductor device in continuation from FIG. 5B;

FIG. 7A is a cross-sectional view illustrating an example of the manufacturing method of the semiconductor device in continuation from FIG. 6A;

FIG. 7B is a cross-sectional view illustrating an example of the manufacturing method of the semiconductor device in continuation from FIG. 6B;

FIG. 8A is a cross-sectional view illustrating an example of the manufacturing method of the semiconductor device in continuation from FIG. 7A;

FIG. 8B is a cross-sectional view illustrating an example of the manufacturing method of the semiconductor device in continuation from FIG. 7B;

FIG. 9A is a cross-sectional view illustrating an example of the manufacturing method of the semiconductor device in continuation from FIG. 8A; and

FIG. 9B is a cross-sectional view illustrating an example of the manufacturing method of the semiconductor device in continuation from FIG. 8B.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

A semiconductor device according to the present embodiment includes a semiconductor element having a first face, a second face located on an opposite side to the first face, and a side face located between the first face and the second face. A first electrode layer is provided on the first face of the semiconductor element. A second electrode layer is provided on the second face of the semiconductor element. An outer edge portion on the second face is more rounded compared to an outer edge portion on the first face. A thickness of the second electrode layer gradually decreases as the second electrode layer extends closer to the side face.

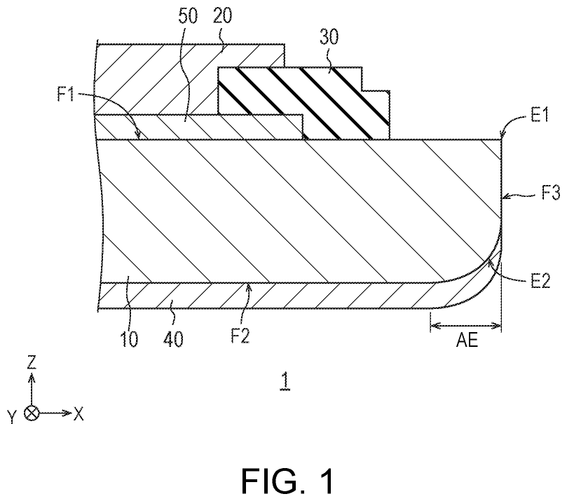

FIG. 1 is a partial cross-sectional view illustrating a configuration example of a semiconductor device according to an embodiment. A semiconductor device 1 includes a semiconductor element 10, a surface electrode 20, an insulating film 30, a backside electrode 40, and a surface electrode 50. FIG. 1 partially illustrates an end portion of the semiconductor device 1. The surface electrode 20 and/or the surface electrode 50 are an example of a first electrode layer.

For example, the semiconductor device 1 may be a power semiconductor device such as an IGBT (Insulated Gate Bipolar Transistor), an HEMT (High Electron Mobility Transistor), a MOSFET (Metal Oxide Semiconductor Field Effect Transistor), or a diode. The semiconductor device 1 is manufactured as an individual piece of semiconductor chip.

The semiconductor element 10 has a first face F1, a second face F2, and a side face F3. The second face F2 is located on a side of the semiconductor element 10 opposite to the first face F1. The side face F3 is located between the first face F1 and the second face F2. For example, the semiconductor element 10 is made of a semiconductor material such as silicon. The semiconductor element 10 has a thickness of, for example, 100 μm or less. The semiconductor element 10 includes a semiconductor substrate, an impurity diffusion layer, an epitaxial growth layer, and others.

On the first face F1 of the semiconductor element 10, the surface electrode 50 formed by sputtering or the like and having a relatively small thickness, the surface electrode 20 formed by plating, vapor deposition, or the like and having a relatively large thickness, and the insulating film 30 are provided.

The surface electrode 20 is a metal film formed on the surface electrode 50 by plating, vapor deposition, or the like into a thickness equivalent to or greater than that of the insulating film 30. The surface electrode 20 and the surface electrode 50 are electrically connected to each other. For example, the surface electrode 50 is made of conductive metal such as titanium, aluminum, or an alloy of aluminum, silicon, and copper. For example, the surface electrode 20 is made of a layered film of conductive metal such as copper, aluminum, titanium, nickel, or gold.

The insulating film 30 is provided to electrically separate the surface electrode 50 and the surface electrode 20 from other semiconductor elements, or is provided to protect the surface electrode 50 or the surface electrode 20. For example, the insulating film 30 is made of an insulating material such as polyimide.

The backside electrode 40 serving as a second electrode layer is provided on the second face F2 of the semiconductor element 10. The backside electrode 40 coats the second face F2 and functions as, for example, a collector electrode of the IGBT serving as the semiconductor device 1 or a drain electrode of the MOSFET serving as the semiconductor device 1. For example, the backside electrode 40 is made of a layered film of conductive metal such as copper, aluminum, titanium, nickel, or gold.

In an outer edge portion AE of the semiconductor element 10, an end portion E2 of an outer edge portion on the second face F2 is more rounded compared to an end portion E1 of an outer edge portion on the first face F1. That is, the end portion E1 on the first face F1 has a relatively small radius of curvature and forms a substantially right angle, while the end portion E2 on the second face F2 has a larger radius of curvature than that of the end portion E1 and is rounded into a curved surface. The outer edge portion AE is a curved surface portion on the second face F2 in the vicinity of the side face F3. The outer edge portion AE may be regarded as a curved surface portion connected from the second face F2 to the side face F3.

The backside electrode 40 also coats the outer edge portion on the second face F2, and coats the curved surface of the end portion E2. Therefore, in the outer edge portion on the second face F2, the backside electrode 40 is curved in the +Z direction from the second face F2 along the side face F3 toward the first face F1. The thickness of the backside electrode 40 gradually decreases in the end portion E2 as the backside electrode 40 extends closer to the side face F3. Furthermore, in plan view as viewed from the vertical direction (Z direction) relative to the first face F1 (a plane parallel to the first face F1), the backside electrode 40 does not extend outward from the side face F3. That is, in plan view as viewed from the Z direction, the backside electrode 40 is provided inside the semiconductor element 10 without protruding outward from the side face F3 of the semiconductor element 10.

The end portion E2 of the semiconductor element 10 is rounded, and the backside electrode 40 coats the end portion E2 from the second face F2 along the side face F3. With this structure, it is possible to reduce or prevent cracks or chipping from the end portion E2 on the second face F2 of the semiconductor element 10. The backside electrode 40 coats the end portion E2 from the second face F2 along the side face F3, and does not protrude outward from the side face F3. Therefore, it is possible to prevent the backside electrode 40 from being unintentionally short-circuited to other wires or semiconductor elements.

Next, a manufacturing method of the semiconductor device 1 according to the embodiment is described.

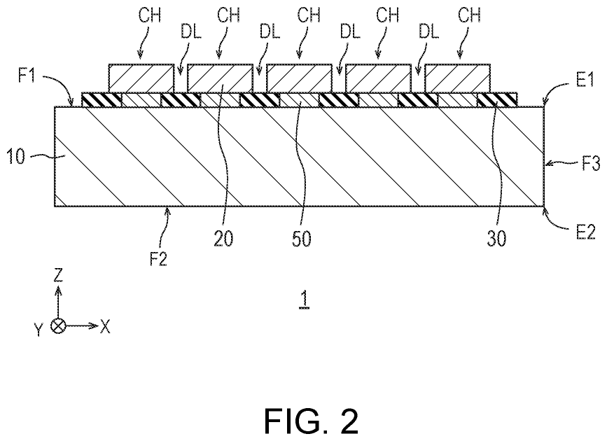

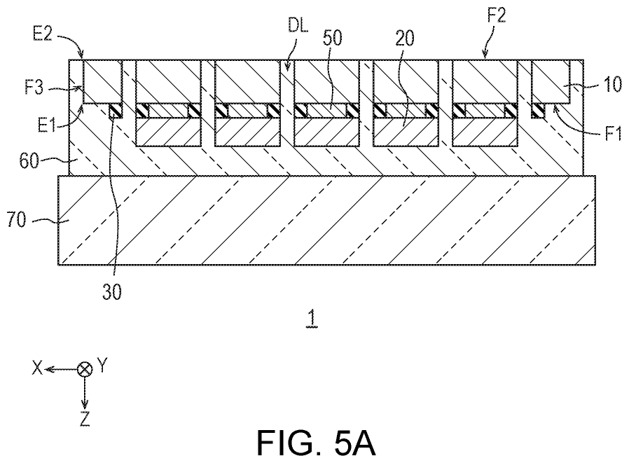

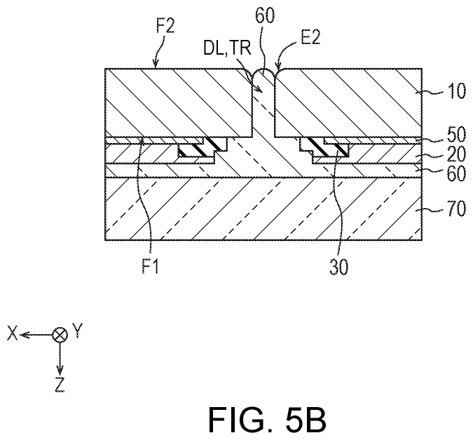

FIGS. 2 to 9B are cross-sectional views illustrating an example of the manufacturing method of the semiconductor device according to the embodiment. FIGS. 5B, 6B, 7B, 8B, and 9B are cross-sectional views illustrating a portion of the semiconductor device between adjacent semiconductor chips in FIGS. 5A, 6A, 7A, 8A, and 9A in more detail.

First, as illustrated in FIG. 2, in the pre-process of semiconductor manufacturing, after the semiconductor element 10 is manufactured, the surface electrode 20, the surface electrode 50, and the insulating film 30 are formed on the first face F1 of the semiconductor element 10.

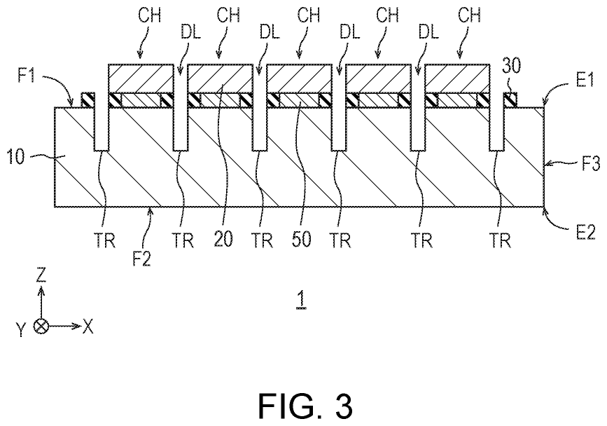

Next, as illustrated in FIG. 3, grooves TR are formed in the semiconductor element 10 from the first face F1 along dicing lines DL between a plurality of semiconductor chips CH. The grooves TR are formed, for example, by blade dicing. The grooves TR are formed into a depth between the first face F1 and the second face F2 of the semiconductor element 10. The grooves TR are formed so as to have a depth greater than the value calculated by adding the thickness of the backside electrode 40 to the thickness of the semiconductor element 10 in a final finished product. This eliminates the need for cutting the backside electrode 40 using a blade or laser, after the material of the backside electrode 40 is formed.

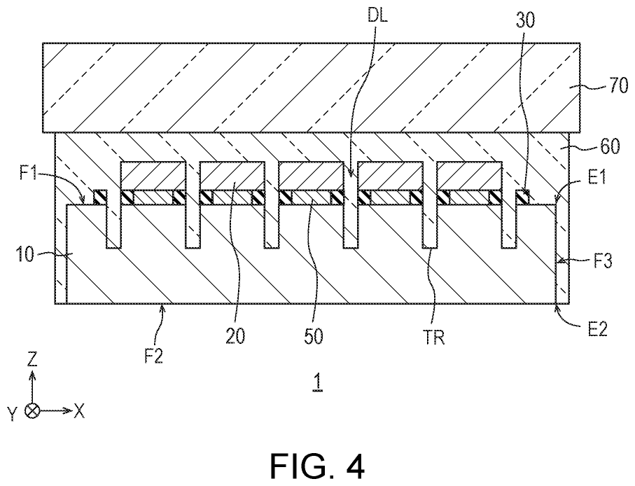

Subsequently, as illustrated in FIG. 4, an adhesive 60 in liquid form is fed onto the first face F1 of the semiconductor element 10. The adhesive 60 is made of, for example, acrylic resin, and is fed so as to fill the grooves TR.

Next, a support substrate 70 is placed on the adhesive 60. The support substrate 70 is bonded to the upper side of the semiconductor element 10 through the adhesive 60. For example, the support substrate 70 is made of an insulating material such as glass.

Subsequently, as illustrated in FIGS. 5A and 5B, the semiconductor element 10 is turned upside down in such a manner that the support substrate 70 is located under the semiconductor element 10. With this process, the second face F2 of the semiconductor element 10 appears on the upper side.

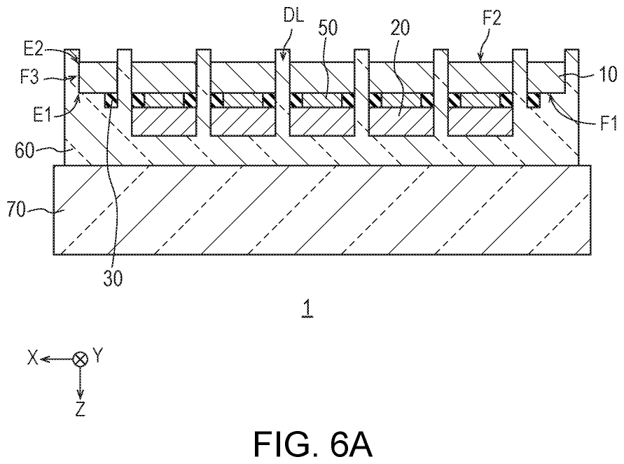

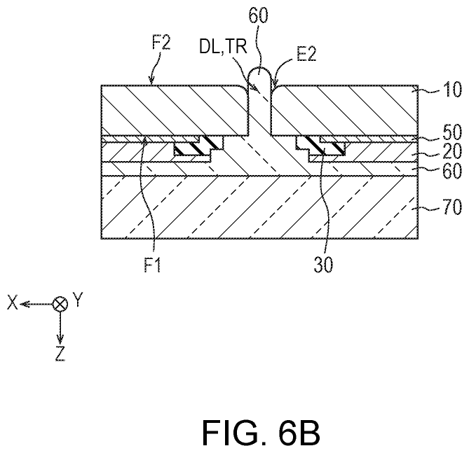

Next, as illustrated in FIGS. 5A and 5B, the second face F2 of the semiconductor element 10 is grounded using a CMP (Chemical Mechanical Polishing) method or the like until the adhesive 60 in the grooves TR is exposed from the second face F2. At this time, as illustrated in FIG. 5B, in a boundary portion between the adhesive 60 and the second face F2 of the semiconductor element 10, etching is further promoted compared to the rest portion of the second face F2 and the adhesive 60. Consequently, the outer edge portion (angular portion) on the second face F2 of the semiconductor element 10 is etched along with the exposed portion of the adhesive 60 and rounded. In this manner, the end portion E2 of the outer edge portion on the second face F2 is formed into a curved surface with a larger radius of curvature than the outer edge portion on the first face F1 in FIG. 1. The thickness of the semiconductor element 10 after the grinding is equal to the sum of a thickness of the semiconductor element 10 in a finished product, a thickness of the backside electrode 40, and an etch-back thickness of the semiconductor element 10 in FIGS. 6A and 6B.

Subsequently, as illustrated in FIGS. 6A and 6B, the second face F2 of the semiconductor element 10 is selectively etched back using a RIE method or a wet etching method. Consequently, the adhesive 60 protrudes from the second face F2. The semiconductor element 10 is etched back to a thickness in the final finished product. At this time, as illustrated in FIG. 6B, the end portion E2 on the second face F2 is etched back, while maintaining the curved surface in FIG. 5B.

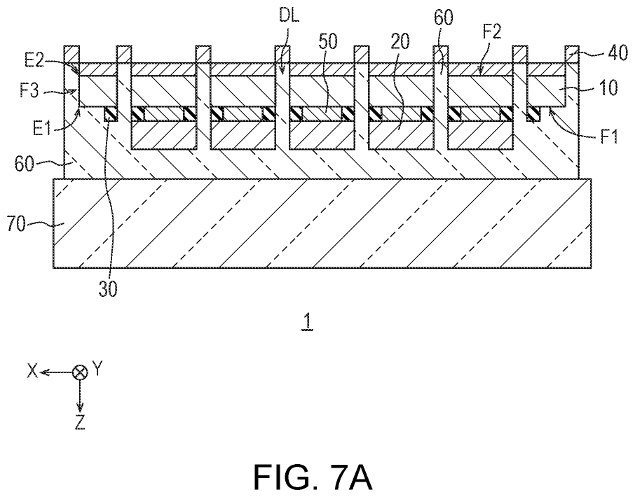

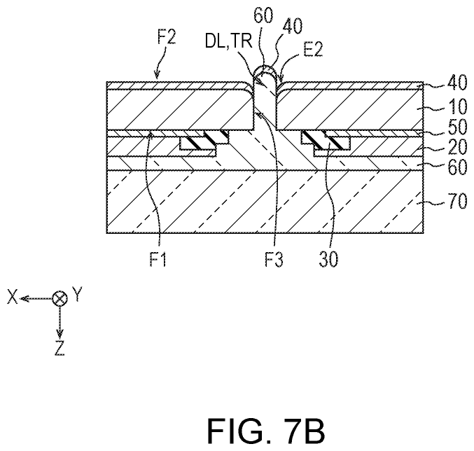

Next, as illustrated in FIGS. 7A and 7B, a material of the backside electrode 40 is deposited on the second face F2 and the adhesive 60 using the sputtering method or the like. At this time, as illustrated in FIG. 7B, the adhesive 60 protrudes from the second face F2, and the end portion E2 on the second face F2 is rounded. Accordingly, the material of the backside electrode 40 enters the boundary portion between the adhesive 60 and the end portion E2 on the second face F2 and coats the rounded end portion E2 on the second face F2. With this process, the material of the backside electrode 40 gradually becomes thinner as this material is closer to the side face F3 in the rounded end portion E2 on the second face F2. Since the semiconductor element 10 is in contact with the adhesive 60 on the side face F3, the material of the backside electrode 40 does not extend outward from the side face F3 in plan view as viewed from the Z direction.

On the other hand, the material of the backside electrode 40 is deposited on the top of a protruding adhesive 60, while being hardly deposited on the side face of the protruding adhesive 60. Accordingly, the side face of the protruding portion of the adhesive 60 is at least partially exposed.

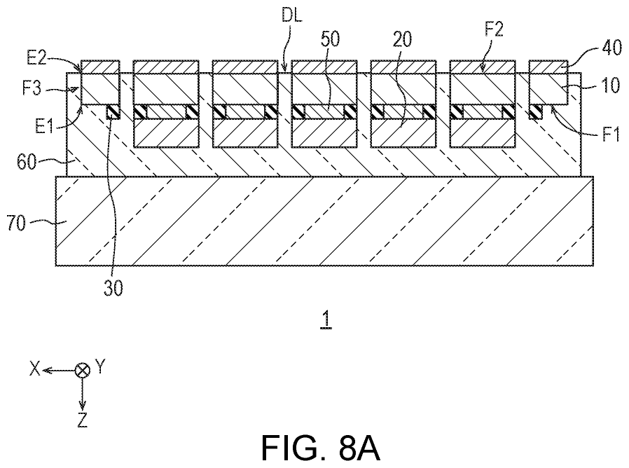

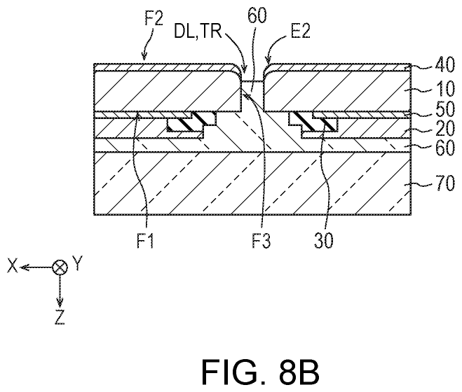

Subsequently, as illustrated in FIGS. 8A and 8B, the adhesive 60 is selectively etched, while the material of the backside electrode 40 remains deposited on the second face F2. At this time, since the side face of the protruding portion of the adhesive 60 is at least partially exposed, the protruding portion of the adhesive 60 is selectively etched. Therefore, the material of the backside electrode 40 on the protruding portion of the adhesive 60 is also removed along with the adhesive 60 (lifting-off). At this time, as illustrated in FIG. 8B, the backside electrode 40 remains deposited on the second face F2 of the semiconductor element 10, and maintains the rounded end portion E2 on the second face F2 in a coated state. The adhesive 60 is somewhat recessed from the backside electrode 40 or the second face F2 toward the first face F1. In this manner, the backside electrode 40 is separated for each semiconductor chip by lifting-off with the adhesive 60. It is thus unnecessary to cut the backside electrode 40 with a blade or laser.

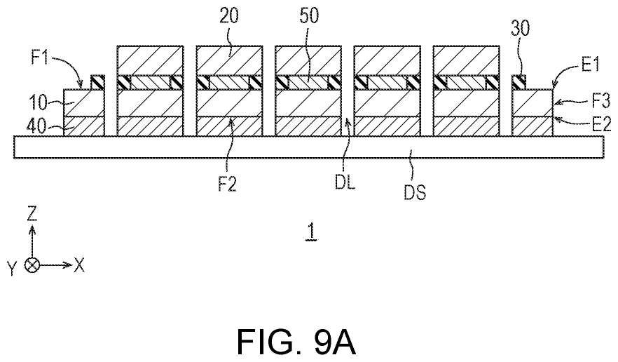

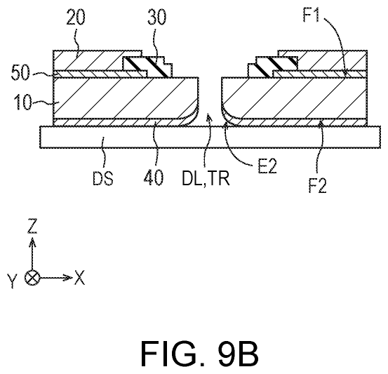

Next, as illustrated in FIGS. 9A and 9B, the semiconductor element 10 is turned upside down. With this process, the first face F1 of the semiconductor element 10 appears on the upper side. The backside electrode 40 located on the lower side of the second face F2 is attached to a dicing sheet DS.

The adhesive 60 is melted to cause the support substrate 70 to come off. Next, the semiconductor element 10 is separated into individual pieces of semiconductor chips, thereby completing the semiconductor device 1 illustrated in FIG. 1.

According to the present embodiment, the semiconductor device 1 includes the backside electrode 40, and uses a DBG (Dicing Before Grinding) method to grind the second face F2 of the semiconductor element 10 after the dicing. However, in the present embodiment, it is unnecessary to cut the material of the backside electrode 40 with a blade, and the material of the backside electrode 40 on the adhesive 60 is lifted-off along with the adhesive 60 in the process of etching the adhesive 60. This prevents formation of burrs on the backside electrode 40, and enables semiconductor chips to be easily picked up from the dicing sheet DS. This can also prevent the backside electrode 40 from being short-circuited to unintended semiconductor elements, wires, or the like. Further, the backside electrode 40 coats the rounded outer edge portion on the second face F2 of the semiconductor element 10. Accordingly, the backside electrode 40 can protect the outer edge portion of the semiconductor element 10, and can reduce or prevent generation of cracks or the like. As a result, the present embodiment can prevent formation of burrs on the backside electrode 40, and enables dicing to be carried out without affecting properties of semiconductor devices.

Further, the backside electrode 40 coats the rounded outer edge portion on the second face F2 of the semiconductor element 10, so that when a semiconductor chip is mounted on a lead frame or a wiring board, a solder (not illustrated) is easily formed into a fillet shape on the backside electrode 40. This can reduce variations in the solder thickness. Consequently, voids are less likely to be generated in the solder under the semiconductor chip.

The backside electrode 40 coats the rounded outer edge portion on the second face F2 of the semiconductor element 10, so that heat dissipation performance of the semiconductor chip also improves.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor element having a first face, a second face located on an opposite side to the first face, and a side face located between the first face and the second face;
a first electrode layer provided on the first face of the semiconductor element; and
a second electrode layer provided on the second face of the semiconductor element, wherein
an outer edge portion on the second face is more rounded compared to an outer edge portion on the first face, and
a thickness of the second electrode layer gradually decreases as the second electrode layer extends closer to the side face.

2. The device of claim 1, wherein the second electrode layer coats the outer edge portion on the second face.

3. The device of claim 1, wherein in a plane parallel to the first face, the second electrode layer does not extend outward from the side face.

4. The device of claim 2, wherein in a plane parallel to the first face, the second electrode layer does not extend outward from the side face.

5. The device of claim 1, wherein in the outer edge portion on the second face, the second electrode layer is curved from the second face along the side face toward the first face.

6. The device of claim 2, wherein in the outer edge portion on the second face, the second electrode layer is curved from the second face along the side face toward the first face.

7. A manufacturing method of a semiconductor device, the method comprising:
forming a first electrode layer on a first face of a semiconductor element having the first face, a second face located on an opposite side to the first face, and a side face located between the first face and the second face;
forming grooves in the semiconductor element from the first face along lines between a plurality of semiconductor chips of the semiconductor element;
feeding an adhesive to the first face so as to fill the grooves;
grinding the second face of the semiconductor element until the adhesive in the grooves is exposed from the second face;
selectively etching back the second face of the semiconductor element in such a manner that the adhesive protrudes from the second face;
depositing a material of the second electrode layer on the second face and the adhesive; and
selectively removing the adhesive along with the material of the second electrode layer on the adhesive, while the material of the second electrode layer remains deposited on the second face.

8. The method of claim 7, comprising:
after feeding the adhesive, and before grinding the second face,
bonding a support substrate to the adhesive on the first face, and
turning the semiconductor element upside down in such a manner that the support substrate is located under the semiconductor element; and
after removing the material of the second electrode layer on the adhesive,
attaching a sheet onto the second electrode layer on the second face, and
turning the semiconductor element upside down in such a manner that the sheet is located under the semiconductor element.

9. The method of claim 8, wherein after attaching the sheet, the semiconductor chips are picked up and mounted on a wiring board.

10. The method of claim 7, wherein
an outer edge portion on the second face is more rounded compared to an outer edge portion on the first face, and
a thickness of the second electrode layer gradually decreases as the second electrode layer extends closer to the side face.

11. The method of claim 8, wherein
an outer edge portion on the second face is more rounded compared to an outer edge portion on the first face, and
a thickness of the second electrode layer gradually decreases as the second electrode layer extends closer to the side face.

12. The method of claim 9, wherein
an outer edge portion on the second face is more rounded compared to an outer edge portion on the first face, and
a thickness of the second electrode layer gradually decreases as the second electrode layer extends closer to the side face.

13. The method of claim 7, wherein the second electrode layer coats an outer edge portion on the second face.

14. The method of claim 8, wherein the second electrode layer coats an outer edge portion on the second face.

15. The method of claim 9, wherein the second electrode layer coats an outer edge portion on the second face.

16. The method of claim 7, wherein in a plane parallel to the first face, the second electrode layer does not extend outward from the side face.

17. The method of claim 8, wherein in a plane parallel to the first face, the second electrode layer does not extend outward from the side face.

18. The method of claim 9, wherein in a plane parallel to the first face, the second electrode layer does not extend outward from the side face.

19. The method of claim 7, wherein in an outer edge portion on the second face, the second electrode layer is curved from the second face along the side face toward the first face.

20. The method of claim 8, wherein in an outer edge portion on the second face, the second electrode layer is curved from the second face along the side face toward the first face.
